(19) United States
(12) Patent Application Publication
(10) Pub. No.: US 2010/0231194 A1
(43) Pub. Date: Sep. 16, 2010

(54) METHOD AND DEVICE FOR MONITORING PLASMA DISCHARGES

(76) Inventors: Hartmut Bauch, Ober-Olm (DE); Matthias Bicker, Mainz/Finthen (DE)

Correspondence Address: Striker, Striker & Stenby, 103 East Neck Road, Huntington, NY, 11743, US

(21) Appl. No.: 12/719,247

(22) Filed: Mar. 8, 2010

(30) Foreign Application Priority Data
Mar. 10, 2009 (DE) 10 2009 011 960.4

(51) Int. Cl. G01R 23/12

(52) U.S. Cl. 324/76.52

(57) ABSTRACT

A method and a device (MON) for monitoring plasma-discharges during a surface treatment process are described. In this process electrodes within a gaseous medium are provided with an alternating voltage (U_{HV}) for generating plasma. The monitoring device (MON) has a detector device (M1) for detecting a measurement signal (I) generated by the alternating voltage (U_{HV}) within the gaseous medium, separating means (M2) for separating signal components above a preset frequency and evaluating means (M3) for evaluating the resulting separated signal components by comparing them with at least one preset reference. Preferably the generating of the plasma is achieved by dielectric barrier discharge and the electric current penetrating the medium, especially the dielectric displacement current, is measured as the measurement signal (I).

### CROSS-REFERENCE

The invention described and claimed herein below is also described in German Patent Application DE 10 2009 011 960.4, filed on Mar. 10, 2009 in Germany. The aforesaid German Patent Application, whose subject matter is incorporated herein by reference thereto, provides the basis for a claim of priority of invention for the invention claimed herein below under 35 U.S.C. 119 (a)-(d).

### BACKGROUND OF THE INVENTION

The invention relates to a method and to a device for monitoring of plasma discharges. In particular, the invention relates to a method and to a device for monitoring plasma discharges (also called plasma ignition) during surface treatment processes in which electrodes in a gaseous medium are charged with an alternating voltage for generating the plasma. Among these there are, for example, methods by which plasma is generated for coating and modifying the surface of miscellaneous products, such as pharmaceutical packing material made of glass and/or plastics. In these methods often the so-called dielectric barrier discharge, also referred to as DBD, is used. In DBD plasma discharges lasting a short time and only a few microseconds are generated by an alternating voltage of for example 10 to 100 kHz, and by dielectric shielding of an electrode.

The stability of plasma discharges and therefore also the quality of such surface treatment processes depends on several conditions, such as pressure, composition of the gas and the surface conditions. Therefore, for industrial practice of such surface treatment processes, adequate measurement methods and means for monitoring the plasma discharges have to be used.

There are methods and devices known for monitoring of plasma discharges by means of optical monitoring of the light emission which can be detected during the occurrence of plasma discharges due to the accompanying generation of photons. For example, with the help of the intensity of the light emission and in particularly of the spectral-optic discrimination of the same, the activity of the treatment processes are monitored and controlled. This approach which is also referred to as “Optical Emission Spectroscopy” or OES, is for example also disclosed in the following publications: US-A-2003223055, EP-A-1630848 and EP-A-0821079. The OES-method, however, has the drawback that high expenses for reduction to practice are needed due to the operation of optoelectronic components, filters, spectrometers and the like.

Other methods for monitoring plasma discharges, which are used if the plasma is generated by RF-Energy, are also known. In this case, a high frequency alternating voltage of for example 13 MHz causes the generation of plasma in a stationary condition. For monitoring the process, the impedance of the plasma is measured by a so-called matchbox. Such methods are, for example, disclosed in the following patents and publications: U.S. Pat. No. 6,291,999 and U.S. Pat. No. 5,576,629. From the U.S. Pat. No. 7,169,625 a method for monitoring of plasma discharges is described, in which a combination of measuring the optical light emission (OES) and the RF-parameters is proposed. However, the RF-parameters, which are to be measured, are not described in detail. Also these known methods need quite a high expense in terms of measurement instruments and devices.

### SUMMARY OF THE INVENTION

Therefore, the object of the present invention is to provide a method and a device for monitoring plasma discharges which can preferably be realized simply and with low costs. In particularly, a method and device for monitoring of plasma discharges is provided which can be applied in combination with dielectric barrier discharge (DBD) in a very advantageous way.

This object is attained by a method comprising the features of the appended method claims and by a device comprising the features of the appended device claims.

Accordingly, it is proposed to detect a measurement signal first, which is an indicator for the electric energy being produced by the alternating voltage in the medium, and then to detect separately such signal parts of the measurement signals which are above a predetermined frequency and, finally, to evaluate the separated signal parts of the measurement signal by comparing them with at least one preset reference or pattern. The device of the invention therefore comprises detector means, separation means and evaluation means.

With the help of the invention, a direct measurement of electric energy in terms of metering time-period can be achieved which can preferably be performed by measuring the electrical current due to the impressing voltage. By performing the separation and the evaluation of the measurement signals, preferably within a corresponding signal processing, a useful signal can be extracted which is relevant for the plasma characteristics and properties. Preferably, when using DBD, a dielectric displacement current which penetrates the medium is measured as the measurement value. This can be done, for example, with the help of a measuring resistor connected in series, which generates a voltage drop and outputs a voltage signal that is proportional to the current. From this measured signal, the signal parts with higher frequencies are separated, and for this purpose, a filtering and/or spectral analysis, in particularly a Fast-Fourier-analysis, can be used. The observed signal components preferably exceed an excitation frequency. This excitation frequency can be for example between 10 and 100 kHz.

Not only the separation of the signal components, but also the evaluation of the separated signal components can be performed by means of a spectral analysis, in particularly of a Fast-Fourier analysis, wherein spectral components corresponding to the signal components are compared with a reference spectrum being used as a reference. The reference spectrum is recorded before the occurrence of a plasma discharge or ignition. Instead of this, the evaluation of the occurring signal components can also be performed by calculating differences in that the signal components of the measurement signals are compared with a reference signal. This reference signal also was recorded before the occurrence of the plasma ignition.

For evaluating the high-frequency-signal components of significance, a threshold can be used which, for example, is a signal value (magnitude, phase) within the spectral range (magnitude, phase) or within the time domain (wave form).

These and further advantageous embodiments also derive from the sub claims.

### BRIEF DESCRIPTION OF THE DRAWING

In the following, the invention will be described in more detail and illustrated by a preferred embodiment with the help of the accompanied figures, wherein:

FIG. 1a is an electrical equivalent circuit diagram for a device for generating plasma for coating a pharmaceutical package, such as a syringe;

FIG. 1b is a block diagram of a device for monitoring a plasma discharge according to the invention;

FIG. 2 is a graphical illustration of a wave form of a measurement signal before the appearance of a plasma discharge;

FIG. 3 is a graphical illustration of a wave form of the measurement signal during the appearance of a plasma discharge;

FIG. 4 corresponds to FIG. 2, but shows the wave form of the measurement signal without the appearance of a plasma discharge and the obtained measurement signal spectrum for a longer time-period than in FIG. 2;

FIG. 5 corresponds to FIG. 3, but shows the wave form of the measurement signal during the appearance of a plasma discharge and the derived measurement signals spectrum for a longer time-period than in FIG. 3; and

FIG. 6 is a flow chart for the method for monitoring a plasma according to the invention.

### DESCRIPTION OF THE PREFERRED EMBODIMENT

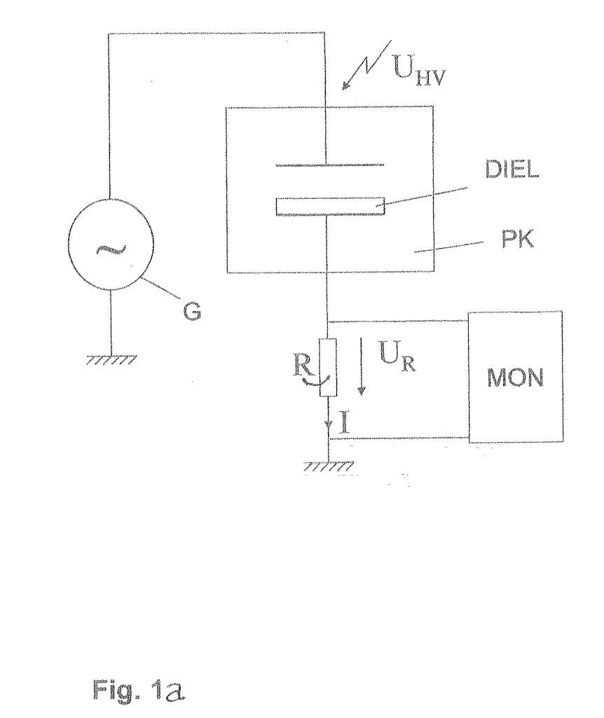

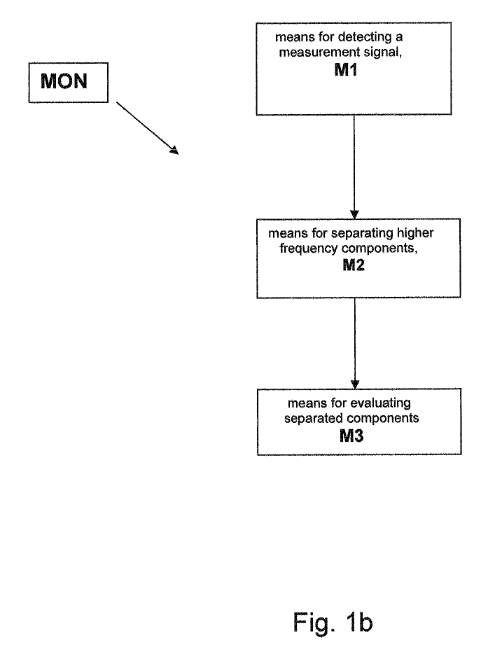

FIG. 1a is a circuit diagram of an electrical equivalent circuit of an arrangement or device for generating plasma by dielectric barrier discharge (DBD). In this equivalent circuit the arrangement has a capacitor comprising a dielectric DIEL, in which a dielectric displacement current I is generated when an electric alternating voltage U_{HV} is applied. In this example, the generator G for example provides a sine-shaped alternating current U_{HV} with an amplitude of 2 kV and a frequency of 15 kHz, which is applied to the electrodes within the plasma chamber PK. One of the electrodes is shielded by a dielectric (for example a glass plate) in order to avoid an ohmic short circuit. Thus, only the dielectric displacement current I is generated, which can be tapped at one of the conductors across the measuring resistor R as corresponding voltage drop U_{R} and which can be supplied to a monitoring device MON for monitoring the plasma discharge, which is shown in more detail in FIG. 1b.

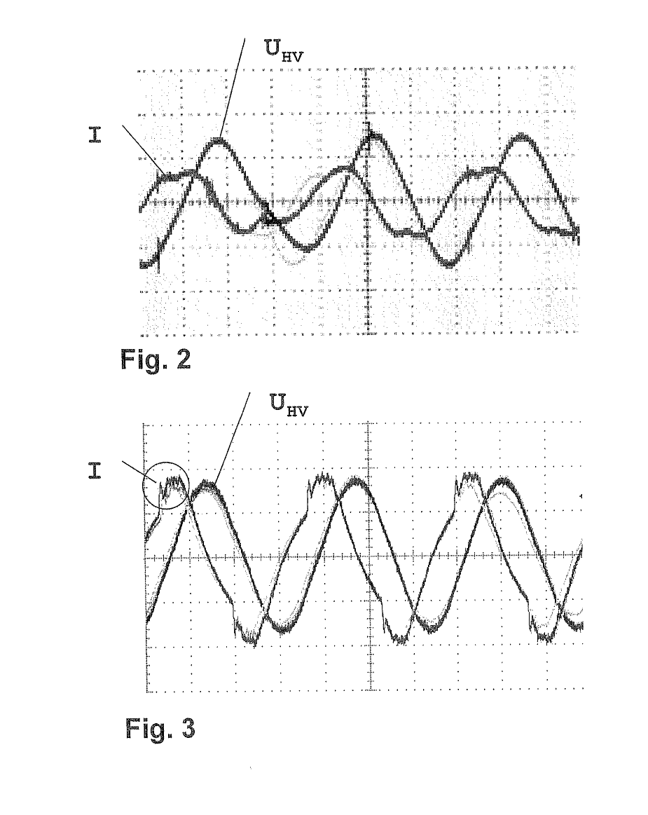

As long as no plasma discharge occurs, a dielectric displacement current I flows which is ideally purely sinusoidal and which follows the generated voltage U_{HV} in a phase shifted manner (also see FIG. 2). This current I is detected as a measurement value by the device MON according to the invention in order to monitor occurring plasma discharges in the medium and in the plasma chamber PK. The amplitude wave forms shown in FIGS. 2 and 3, with respect to the time axis, are provided with the following spacing (line boxes): On the time axis one box equals 2 microseconds and on the amplitude axis, one box equals 1000 Volts or 10 milliamperes.

As these figures clearly show, the basis of the invention is that already by measuring the current I or a corresponding measurement value, the energy status in the plasma chamber PK and, in particularly the occurrence of plasma discharges or plasma ignitions, can reliably be detected. Therefore, no optical measurement means or the like are needed. Further to this and by means of the evaluation of the measurement value I, characteristics of the quantity and quality of the plasma discharges can be derived.

Because the electrical current I rapidly increases for a limited time period during the appearance of plasma discharges, the characteristic signal wave form can be detected (see in FIG. 3 the encircled areas). This is because of the fact that, in the areas of the maximum amplitudes of the alternating voltage U_{HV} above, a system-specific field strength, the effective dielectric DIEL changes and the impedance is lowered so that the current I rapidly increases and a plasma ignition occurs. Then, during the ongoing time period of the alternating voltage, the amplitude value is again reduced and the plasma expires; then the current I again corresponds to a pure sinusoidal or sine-shaped electric displacement current. When the plasma appears then periodic current pulses (see FIG. 3) occur in the upper area of the positive and in the lower area of the negative half-wave, which have typical characteristics and therefore, each indicate a plasma ignition.

In other words, the inventive method comprises measuring electric energy in a time resolved manner, here in the form of a current measurement by an impressed voltage. By applying a single signal processing function or a combination of signal processing functions, such as discriminators, high and low pass filters, Fourier-transformations, spectrum analysis, a useful signal can be extracted from the measured signals, wherein the useful signal reflects the characteristics or properties of the plasma. This can also be achieved by means of the appropriate evaluation logic or intelligent computing technology and adopted software. The derived useful signal cannot only be used for process monitoring, but also for process control.

The invention therefore monitors the appearance of an electric plus signal and then detects the occurrence of a gas discharge or gas ignition. The monitoring device MON (see FIG. 1b) comprises appropriate means or units in particularly detector means M1, which detects a measurement signal, separating means M2, which separates higher frequency signal components from the measurement signal and evaluation means M3, which evaluates the separated signal components by comparison.

For explaining the invention in more detail, FIG. 4 shows the wave form in time of the electric alternating voltage U_{HV} over a larger time period and shows the dielectric displacement current I, resulting there from. In the lower section of the figure, the spectral representation of the Fourier transformation result FFT of the current signal I is shown. FIG. 4 refers to a time period before the appearance of a plasma ignition. Accordingly, and in particular the higher frequency ranges above of 500 kHz do not show considerable spectral components.

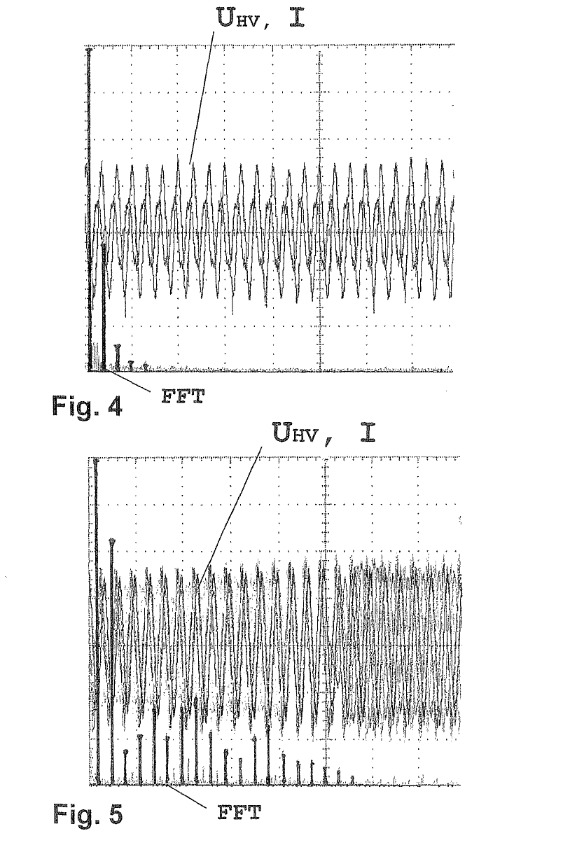

FIG. 5 refers to a situation in which a plasma discharge or plasma ignition occurs. Again, the alternating voltage U_{HV}, the current I as well as the Fourier transformation result FFT are shown. It is clearly shown that now also in the higher frequency ranges, there are considerable spectral components.

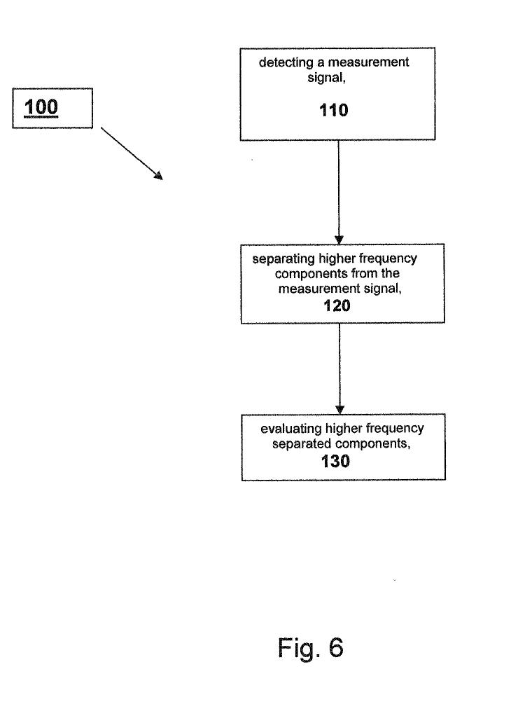

FIG. 6 finally shows a flowchart of the method 100 of the invention, comprising the steps 110 to 130. The method 100 in particularly comprises the following steps (also see the before described FIGS. 1 to 5):

In a first step 110 (FIG. 6), the measurement signal is detected which represents a measurement value which is in this case of the preferred embodiment the current I, representing the electrical energy being generated by the alternating voltage UHF within the medium. In a next step 120, those signal components of the measurement signals are separated, which are above an excitation frequency. Here the excitation frequency is, for example, 100 kHz and the separated signal components are above this within a range of about 500 kHz. In a succeeding step 130 then the separated signal components of the measurement signals I are evaluated by comparing them with at least one preset reference. The invention thus proposes to monitor the appearance of electrical pulse signals in order to detect the occurrence of a gas discharge or a gas ignition from them.

The method and the device MON executing the same (see FIG. 1) are in particularly useful for monitoring dielectric barrier discharges. In these cases, the atmospheric plasma is produced within a hollow body made of glass, plastics or the like. As a gaseous medium, helium or argon or a mixture of those gases can be used. A high voltage generator G having an output power of for example 10 kW (SS) is provided. The alternating voltage U_{HV} may have a frequency of for example 10 to 100 kHz, which corresponds to the excitation frequency. The alternating voltage U_{HV} is supplied to a tip or an electrode located within the hollow body. There is a metallic cover outside and surrounding the hollow body, which acts as the counter electrode. The gaseous medium is guided into the hollow body through a specific hole of the hollow body. Thus, the structure as shown in FIG. 1 represents a co-axial shaped capacitor. When the alternating voltage U_{HV} is applied, then a dielectric displacement current flows phase shifted by 90°. Once the plasma occurs or appears, it makes a partial short circuit for the alternating current via the gas area between the central electrode and the glass wall.

FIGS. 3 and 4 show wave forms of the voltages, currents and show the spectra analysis for the described embodiment. For example, by means of a Fast Fourier transformation, the current signal can be subjected to a spectral analysis. In case of a plasma ignition, then in the spectrum of the measurement signal, a large number of high frequency spectral components can be observed. Then the spectral frequencies and/or their amplitudes being evaluated by means of the measurement signals and the spectral analysis can easily be put into coordination in an empirical way with the existing plasma conditions, such as pressure, gas flux and composition, surface condition and the like. In this way, monitoring of plasma discharges is possible with the use of a few measuring means. Also the overall process can be effectively controlled.

### PARTS LIST

G High frequency generator
U_{HV} alternating voltage (20 to 100 kHz)
DIEL Dielectric material
PK Plasma chamber
MON Monitoring Device
M1 Detector means (including resistor R)
M2 Separating means (here: a filter)
M3 Evaluation means (including FFT analyzer)
R Measuring resistor
I Measurement value or measurement signal
   (here: a dielectric displacement current)
U_{R} Voltage drop (Measuring voltage)
FFT Spectrum of the measurement signal I

What is claimed is:

1. A method (100) of monitoring plasma discharges occurring during a surface treatment process, wherein electrodes within a gaseous medium are supplied with an alternating voltage (U_{HV}) for generating a plasma, said method comprising the steps of:
a) detecting a measurement signal (I) representing a measurement value of the electric energy produced by said alternating voltage (U_{HV}) in said medium (step 110);
b) separating signal components of the measurement signal (I) above a preset frequency from the measurement signal to form separated signal components (step 120); and
c) evaluating the separated signal components of the measurement signal (I) by comparing them with at least one preset reference (step 130).

2. The method (100) as defined in claim 1, wherein the generating of the plasma occurs by dielectric barrier discharge.

3. The method (100) as defined in claim 1, wherein an electric current which penetrates the medium is measured as said measure signal (I).

4. The method (100) as defined in claim 3, wherein the electric current is a dielectric displacement current.

5. The method (100) as defined in claim 1, wherein the separating of the signal components of the measurement signal (I) is performed by a filtering and/or by a spectral analysis.

6. The method (100) as defined in claim 5, wherein said spectral analysis is a Fast-Fourier-Analysis (FFT).

7. The method (100) as defined in claim 1, wherein for separating of said signal components of the measurement signal (I) the preset frequency exceeds an excitation frequency, and further comprising presetting the preset frequency.

8. The method (100) as defined in claim 5, wherein spectral components, corresponding to the signal components, are compared with a reference spectrum used as said preset reference.

9. The method (100) as defined in claim 8, further comprising recording said reference spectrum before the generation of the plasma.

10. The method (100) as defined in claim 1, wherein the evaluating of the separated signal components of the measurement signal (I) is performed by a computation of a difference, whereby the signal components of the measurement signal (I) are compared with a reference signal.

11. The method (100) as defined in claim 10, further comprising recording said reference spectrum before the generation of the plasma.

12. The method (100) as defined in claim 5, wherein the evaluating of the separated signal components of the measurement signal (I) is performed by means of a threshold and said threshold corresponds to a signal value in the spectral domain or the time domain.

13. A device (MON) for monitoring plasma discharges occurring during a surface treatment process, wherein electrodes within a gaseous medium are supplied with an alternating voltage (U_{HV}) for generating a plasma, said device comprising:
detector means (M1) for detecting a measurement signal (I) representing a measurement value of the electric energy generated by said alternating voltage (U_{HV});
separating means (M2) for separating signal components of the measurement signal (I) above a preset frequency from the measurement signal to form separated signal components; and
evaluating means (M3) for evaluating the separated signal components of the measurement signal (I) by comparing said separated signal components with at least one preset reference.

20. The device (MON) as defined in claim 13, wherein the evaluating means (M3) comprises comparison means for comparing the signal components of the measurement signal with a reference spectrum or a reference signal.
